(19) United States
(12) Patent Application Publication
(10) Pub. No.: US 2023/0105007 A1
(43) Pub. Date: Apr. 6, 2023

(54) ARTIFICIAL INTELLIGENCE (AI) DEVICES WITH IMPROVED THERMAL STABILITY AND SCALING BEHAVIOR

(71) Applicant: International Business Machines Corporation, Armonk, NY (US)

(72) Inventors: Injo Ok, Loudonville, NY (US); Alexander Reznicek, Troy, NY (US); Youngseok Kim, Upper Saddle River, NJ (US); Soon-Cheon Seo, Glenmont, NY (US)

(21) Appl. No.: 17/493,813

(22) Filed: Oct. 4, 2021

(51) Int. Cl. H01L 45/00; H01L 27/24

(52) U.S. Cl. CPC H01L 45/144; H01L 27/2463; H01L 45/06; H01L 45/1233; H01L 45/126; H01L 45/1675

(57) ABSTRACT

A phase change memory semiconductor structure includes a substrate; a landing pad located in the substrate; a dielectric located outwardly of the substrate; a heater element located in the substrate outward of the landing pad; a stack including an inner undoped chalcogenide layer outward of the dielectric, a doped chalcogenide layer outward of the inner undoped chalcogenide layer, and an outer undoped chalcogenide layer outward of the doped chalcogenide layer; and at least one lateral conductive metal layer associated with the stack.

### BACKGROUND

The present invention relates generally to the electrical, electronic and computer arts and, more particularly, to phase change memory (PCM) cells useful, for example, in artificial intelligence (AI) applications, and the like. PCM is a type of non-volatile random-access memory, making use of properties of chalcogenide glass. Heat produced by the passage of an electric current through a heating element, generally made of titanium nitride, can quickly heat and quench the glass, making it amorphous, or hold it in its crystallization temperature range for some time, thereby switching it to a crystalline state.

Chalcogenide materials are an emerging class of commercial electronic materials that exhibit switching, memory, logic, and processing functionality. The basic principles of chalcogenide materials were developed in the 1960s and much effort since then has led to advancements of the underlying science and an expansion of the field of application of chalcogenide materials.

One type of PCM chalcogenide memory device utilizes the wide range of resistance values available for the active chalcogenide material as the basis of memory operations (i.e., to encode information). Each resistance value corresponds to a distinct structural state of the chalcogenide material, and one or more of the states can be selected and used to define operational memory states. Chalcogenide materials, as noted, exhibit a crystalline state or phase as well as an amorphous state or phase. Different structural states of a chalcogenide material differ with respect to the relative proportions of crystalline and amorphous phase in a given volume or region of chalcogenide material. The range of resistance values is bounded by a SET state and a RESET state of the chalcogenide material. The SET state is a low resistance structural state whose electrical properties are primarily controlled by the crystalline portion of the chalcogenide material and the RESET state is a high resistance structural state whose electrical properties are primarily controlled by the amorphous portion of the chalcogenide material.

Utilizing phase change memory for analog computing typically requires memory cells with a resistance that changes linearly with programming pulses and is predictable and repeatable. Amorphous phase change materials often suffer from “resistance drift,” whereby the resistance of the cell changes over time, which makes the resistance of the cell unpredictable. To mitigate resistance drift, a “projection segment” (a parallel resistor that bypasses current around the amorphous volume), is added to the cell. Depending on the geometry of the cell and the projection segment, however, the cell resistance can become very non-linear. For an exemplary “mushroom” cell design using a projection segment that covers the bottom of the phase change material (Ge₂Sb₂Te₅ (GST)), the simulated resistance of the cell is highly non-linear with the side length of the amorphous volume.

Phase change material (PCM) devices with resistive liners (e.g. projection segments) provide better cycling endurance and reduce resistance drift of the device due to bypass of current through the amorphous phase-change volume during READ operations. Seung-Wook Ryu, Young-Bae Ahn, Jong-Ho Lee, and Hyeong-Joon Kim, Thermal Stability of SiO₂ Doped Ge₂Sb₂Te₅ for Application in Phase Change Random Access Memory, JSTS: Journal of Semiconductor Technology and Science. 2011; 11(3):146-52, discloses that the addition of a small amount of SiO₂ into GST film restricts the deterioration of physical and chemical properties of GST film, resulting in better thermal stability after isothermal annealing. Multi GST/dGST/GST (i.e., undoped GST/doped GST/undoped GST) structures provide better thermal stability, without process issues such as liner or heater oxidation, during dGST deposition. Wabe W. Koelmans, Abu Sebastian, Vara Prasad Jonnalagadda, Daniel Krebs, Laurent Dellmann, and Evangelos Eleftheriou, Projected phase-change memory devices, Nature communications, 2015 Sep. 3; 6(1):1-7 discloses techniques to decouple the physical mechanism of resistance storage from the information-retrieval process.

Referring to FIG. 1, the paper by SangBum Kim et al., One-Dimensional Thickness Scaling Study of Phase Change Material (Ge2Sb2Te5) Using a Pseudo 3-Terminal Device, IEEE transactions on electron devices, 2011 Apr. 5; 58(5):1483-9, indicates that thick GST and a short heater cause the hottest spot to be located above the heater inside the GST during RESET programming. By inserting an additional top electrode (ATE) metal layer 109, the hottest spot is confined in the GST1 107 layer, because the ATE metal is thermally more conductive than GST and effectively spreads the heat in the lateral direction (note bold arrows labeled “Low R path”). This results in full amorphization of the GST1 layer 107 (amorphous GST1 is at 115) and a dome-shaped amorphous region 117 in the GST2 layer 111. Note bottom electrode 101, substrate 103 (e.g., a dielectric such as SiO₂), bottom heater 105, and TiN 113.

### BRIEF SUMMARY

Principles of the invention provide techniques for artificial intelligence (AI) devices with improved thermal stability and scaling behavior. In one aspect, an exemplary phase change memory semiconductor structure includes a substrate; a landing pad located in the substrate; a dielectric located outwardly of the substrate; a heater element located in the substrate outward of the landing pad; a stack including an inner undoped chalcogenide layer outward of the dielectric, a doped chalcogenide layer outward of the inner undoped chalcogenide layer, and an outer undoped chalcogenide layer outward of the doped chalcogenide layer; and at least one lateral conductive metal layer associated with the stack.

In another aspect, an exemplary phase change memory semiconductor array includes a plurality of word lines; a plurality of bit lines intersecting the plurality of word lines at a plurality of cell locations; a plurality of access devices, controlled by the word lines, at the plurality of cell locations; and a plurality of phase change memory cells located at the plurality of cell locations. Each of the phase change memory cells includes a substrate portion; a landing pad located in the substrate portion; a dielectric portion located outwardly of the substrate portion; a heater element located in the substrate portion outward of the landing pad; a stack including an inner undoped chalcogenide layer outward of the dielectric, a doped chalcogenide layer outward of the inner undoped chalcogenide layer, and an outer undoped chalcogenide layer outward of the doped chalcogenide layer; at least one lateral conductive metal layer associated with the stack; and a top electrode outward of the outer undoped chalcogenide layer. One of the top electrode and the landing pad is coupled to a corresponding one of the bit lines and another of the top electrode and the landing pad is coupled to a corresponding one of the access devices.

In a further aspect, an exemplary method of forming a phase change memory semiconductor structure includes depositing a dielectric outwardly of a substrate having a landing pad located therein; patterning the dielectric with a heater formation cavity; forming a heater element in the heater formation cavity; forming a stack outward of the dielectric, the stack including an inner undoped chalcogenide layer outward of the dielectric, a doped chalcogenide layer outward of the inner undoped chalcogenide layer, and an outer undoped chalcogenide layer outward of the doped chalcogenide layer; and forming at least one lateral conductive metal layer associated with the stack.

As used herein, “facilitating” an action includes performing the action, making the action easier, helping to carry the action out, or causing the action to be performed. Thus, by way of example and not limitation, instructions executing on one processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:

PCM cells with improved thermal stability;

PCM cells with improved scaling behavior;

one or more exemplary structures improve one or more of retention, memory window, endurance characterization and PCM resistance drift coefficient.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 shows a prior-art memory cell;

FIGS. 2-6 show various stages in fabrication memory cells in accordance with aspects of the invention;

FIG. 7 shows cross sections of portions of memory cells according to various embodiments of the invention;

FIGS. 8 and 9 show exemplary sidewall formation, according to aspects of the invention;

FIG. 10 shows cross sections of portions of memory cells according to various embodiments of the invention; and

FIG. 11 shows a memory array of cells in accordance with aspects of the invention.

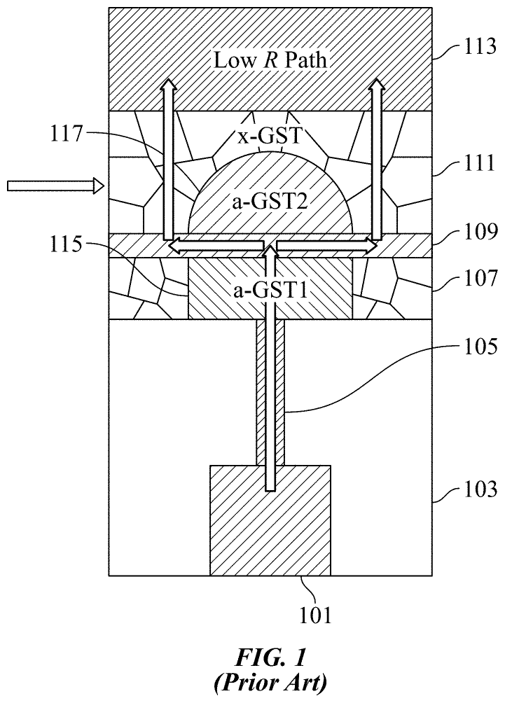

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

One or more embodiments provide techniques for forming and oxygen-free interface dGST cell, for using a dGST with bottom and top GST to avoid oxidation on the heater or bottom liner and top electrode, and/or for providing an optional bottom liner to improve resistance drift without any oxidation process. Furthermore, one or more embodiments provide a structure of a mushroom cell structure to improve endurance and resistance drift and programing current, a WET damage-free GST cell, and/or a pseudo-terminal metal liner inside a GST mushroom cell. One or more embodiments employ a metal with low thermal conductivity and high electrical conductivity (lower than other metals but higher than dielectric). Furthermore, one or more embodiments provide techniques for incorporating pseudo-terminal metal inside of a GST cell, a laminated GST cell with dGST and GST, techniques for forming oxidation-free interface GST, and/or a phase change memory structure with a GST/dGST/GST laminated cell. With regard to the WET damage-free GST cell, the interface between dGST and the bottom heater can be damaged during GST etching (reactive ion etching (ME) followed by WET (dilute hydrofluoric acid (DHF)-based Wet process)). Advantageously, by placing dGST on top of a thin layer of GST, the interface is much stronger than a direct dGST interface, during RIE and WET processes.

In prior art devices, current flows from the bottom electrode 101 to the GST. Prior art devices employ undoped GST. One or more embodiments employ dGST (doped GST; e.g., GST doped with silicon oxide) between very thin layers of GST. Undoped GST is close to crystalline and easily passes current. However, when doped with SiO₂, the resistivity (and thus resistance) is much higher and the current is much lower (although the resistivity of dGST moves closer to that of undoped GST as temperature increases). PCM works by passing current in the crystalline state and blocking current in the amorphous state. The use of dGST typically requires a post-sputtering oxygen flow plasma vapor deposition (PVD) step. Typical sputtering includes Germanium, Antimony, and Tellurium with oxygen flow and silicon post-sputtering. During this process, it is undesirable if the metal heater 105 oxidizes. Furthermore, a metal oxide is often undesirably formed between the metal and the dGST.

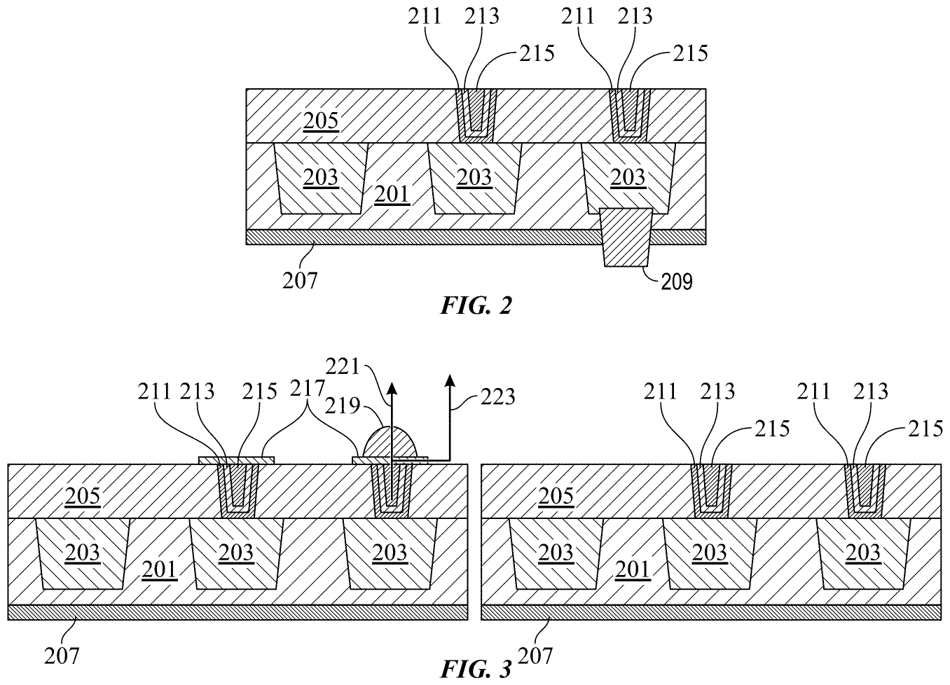

Consider now an exemplary integration scheme for forming PCM cells with improved thermal stability and scaling behavior. FIG. 2 shows bottom heater formation. Note the dielectric cap layer 207 (e.g., SiN, SiCN, or conventional dielectric cap layer (NBLoK nitrogen-doped silicon carbide, as will be familiar to the skilled artisan), low-k dielectric 201 (can also be tetraethyl orthosilicate (TEOS)), landing pads 203, electrically insulating high-temperature ceramic 205 such as SiN, and wiring connection 209 (e.g., copper or other suitable metal). Landing pad materials can include, for example, Tungsten (W), Tantalum Nitride (TaN), Titanium Nitride (TiN), Iridium (Ir), or the like. Layer 211 is a material with high electrical resistance (e.g., TaN); layer 213 is a material with low electrical resistance (e.g., TiN); and layer 215 is a material with high electrical resistance (e.g., TaN). Generally, layer 211 can include, for example, high resistivity TaN or metal nitride or any dielectric; layer 213 can include, for example, TiN or any low resistivity metal such as Ru, Ir, W, Pt, etc.; and layer 215 can include, for example, high resistivity TaN or metal nitride or any dielectric. To form the heater, deposit SiN dielectric 205. Pattern layer 205 to make the openings for the heaters and then fill them with layers 211, 213, 215. Carry out planarization (e.g., chemical mechanical polishing (CMP)) down to a suitable thickness of layer 205 (e.g., 50 nm).

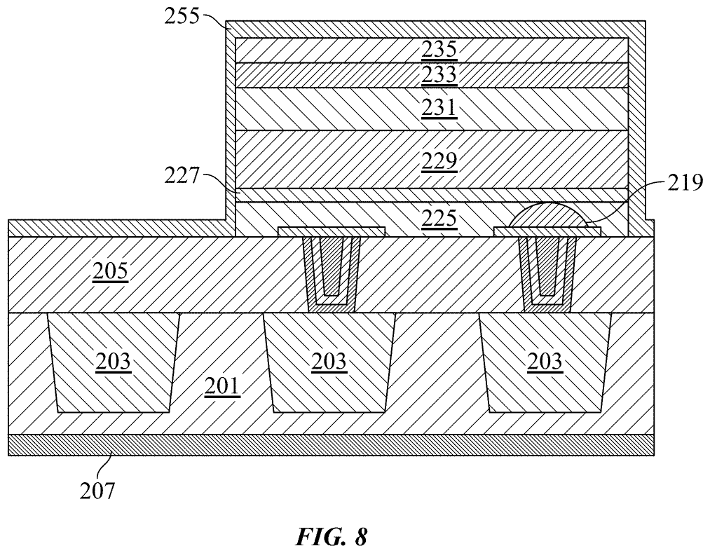

FIG. 3 shows the addition of a projection liner 217, which allows current to easily pass through. The projection liner is formed in the left-hand structure but not the right-hand structure. Please note that in FIGS. 3, 4, 5, 6, and 10, the left and right views represent different embodiments (with and without projection liner 217), on different substrates. Note the amorphous PCM (dome 219). Liner 217 allows current to follow the path of bold arrow 223 through the crystalline GST 225 (seen in FIG. 8. Note, the dome 219 is shown in FIG. 3 to permit uncluttered illustration; at this fabrication stage GST 225, discussed below, is not actually present yet. Programming requires changing phase. Reading involves application of a small amount of voltage and then the current is read out. Current cannot readily follow bold arrow 221 to pass through the amorphous dome 221. Exemplary suitable materials for liner 217 include TaN, a-C (amorphous carbon), SiN, Carbon nano tube, TiN, metal nitride, dielectric, metal, and the like.

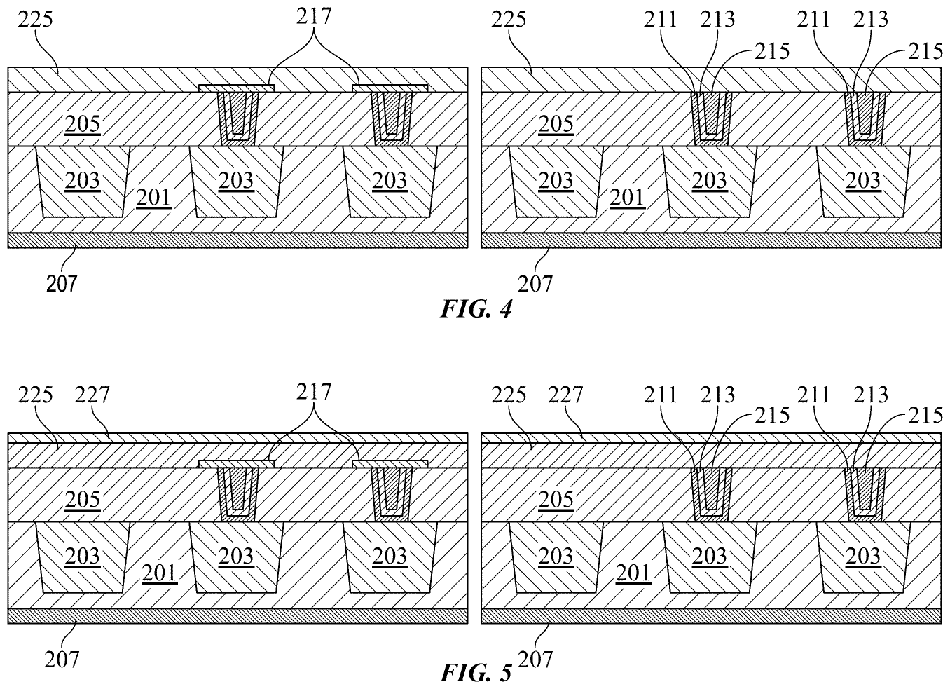

FIG. 4 shows deposition of GST 225. In one or more embodiments, instead of dGST deposition, undoped GST is deposited on top of the heater.

FIG. 5 depicts metal liner (pseudo terminal metal) deposition 227. Thick GST (e.g., 1 nm-20 nm of GST+1 nm-5 nm of ATE+10 nm-100 nm of dGST+1 nm-20 nm of GST) and a short (e.g., critical dimension (CD)=10 nm−50 nm) heater typically cause the hottest spot to be located above the heater inside the GST during RESET programming. By inserting the additional top electrode (ATE) 227, the hottest spot is confined in the GST1 layer 225, because the ATE metal is thermally more conductive than GST and effectively spreads the heat in the lateral direction. This results in full amorphization of the GST1 layer and the corresponding dome-shaped region 219.

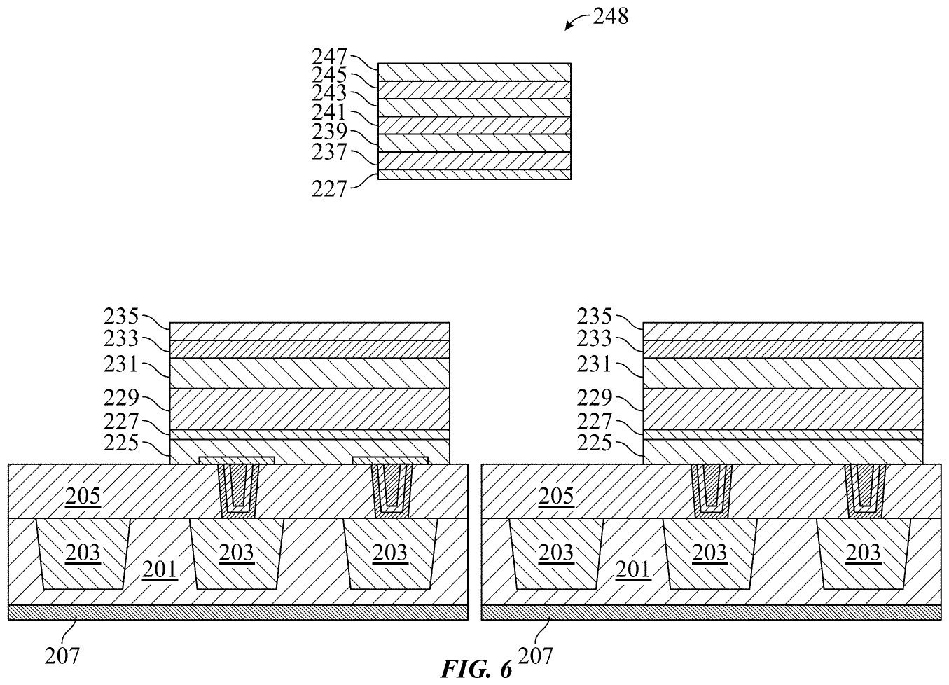

FIG. 6 depicts patterning of the GST with the top electrode (TE) (e.g., TiN) and hard mask (HM) (e.g., SiN). In particular, a dGST layer (e.g., SiO doped) 229 is deposited on metal 227. An additional layer of undoped GST 231 is deposited on dGST layer 229, followed by TE 233 and HM 235. The left-hand view in FIG. 6 shows a first option while the right-hand view in FIG. 6 shows a second option. Note that layers 229, 231 could instead be constituted of multiple layers of alternating dGST 237, 241, 245 and undoped GST 239, 243, 247, as seen at 248. The ATE material 227 can be TiN, TaN, a-C, metal nitride, any metal type, or Si, Ge such as a semiconductor.

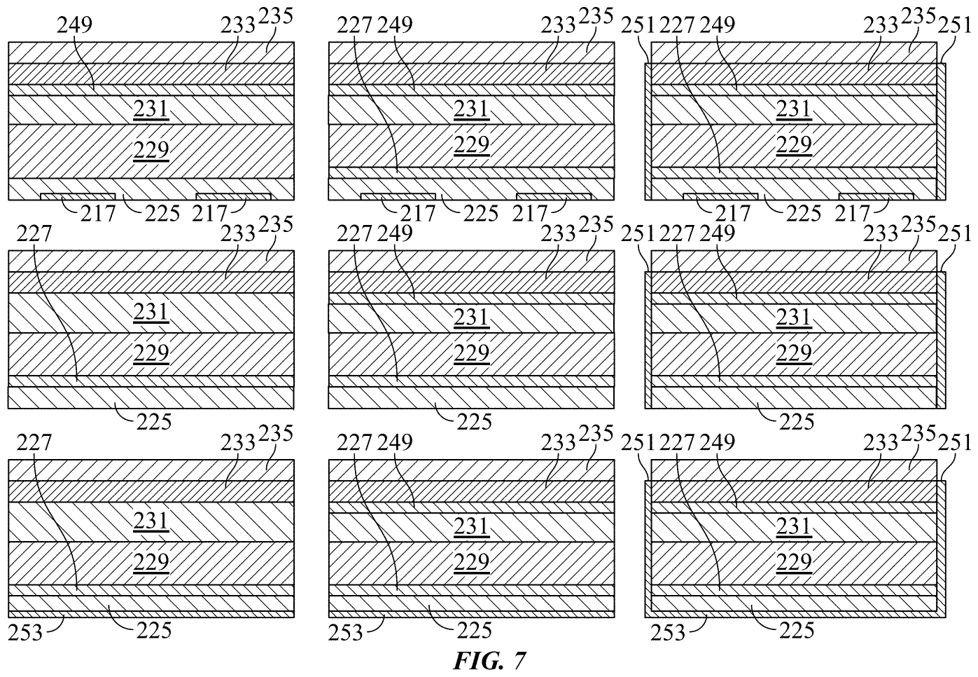

FIG. 7 shows three possibilities for the first option (top row), three possibilities for the second option (middle row), and three possibilities for a third option (bottom row). In the left-most view in the top row, metal 227 is omitted but a metal layer 249 is formed between layers 231, 233. In the middle view in the top row, metal 227 is included and a metal layer 249 is also formed between layers 231, 233. In the right-most view in the top row metal 227 is included and a metal layer 249 is also formed between layers 231, 233. Further, the sidewalls, as shown at 251, include side ATE lines such as TiN, TaN (high-resistance), and a-C or Si, Ge, or any semiconductor also on the sidewall, to provide current path and thermal confinement.

In the left-most view in the middle row, metal 227 is included. In the middle view in the middle row, metal 227 is included and a metal layer 249 is also formed between layers 231, 233. In the right-most view in the middle row metal 227 is included and a metal layer 249 is also formed between layers 231, 233. Further, the sidewalls, as shown at 251, include side ATE lines such as TiN, TaN (high-resistance), and a-C or Si, Ge, or any semiconductor also on the sidewall, to provide current path and thermal confinement.

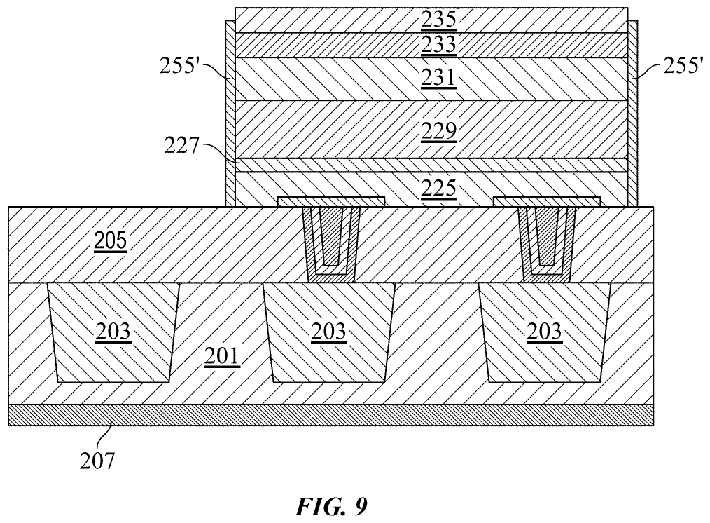

In the left-most view in the bottom row, metal 227 is included. In the middle view in the bottom row, metal 227 is included and a metal layer 249 is also formed between layers 231, 233. In the right-most view in the bottom row metal 227 is included and a metal layer 249 is also formed between layers 231, 233. Further, the sidewalls, as shown at 251, include side ATE lines such as TiN, TaN (high-resistance), and a-C or Si, Ge, or any semiconductor also on the sidewall, to provide current path and thermal confinement. In each of the views in the bottom row, the bottom also includes TiN, TaN (high-resistance), and a-C at 253. In particular, the embodiments of the last row include a long (same length as GST/TiN/SiN) projection liner while the embodiments of the top row have a patterned liner. FIGS. 8 and 9 show an exemplary way to etch options such as in the right-hand column of FIG. 7 after wrap around metal line deposition.

Furthermore in this regard, FIG. 8 shows a suitable process flow for the third option (bottom row in FIG. 7). A layer of TiN, TaN (high-resistance), and a-C (can also be a semiconductor such as Si or Ge) 255 is deposited over the left-hand structure in FIG. 6. Current goes around the amorphous dome 219 into the GST 225 and then up. Etching, such as reactive ion etching (ME), is carried out to recess material 255 and obtain the final structure shown in FIG. 9, where the recessed material 255 is designated as 255′. Thus, the conformal deposition and etch process provides a side projection liner (or ATE) which can also confine heat and thermal loss, advantageously making the PCM efficient; this liner also provides a current path during the reading process. During read-out, the current cannot go through the amorphous dome 219. TaN is thermally insulating but has an electrical resistance between that of GST and dGST. One or more embodiments employ dGST between a sandwich of GST. The stack includes the bottom electrode, heater, projection liner, GST, pseudo-terminal metal, dGST, GST. It is possible to have multi-layers as per the detail 248 in FIG. 6.

By way of review, FIG. 3 shows bottom projection liner deposition; FIG. 4 shows GST deposition; and FIG. 5 shows deposition of ATE metal. As noted, prior-art implementations using only dGST can result in damage the heater (it is desirable that the heater should be pure metal without any oxide). FIG. 7 shows three different options. Metal liners 227, 249 can include, for example, TaN (Tantalum Nitride), which has a resistance value between that of GST and dGST. The use of undoped GST layers 225, 231 provides an oxidation-free interface at the top and bottom. The right-hand column in FIG. 7 shows use of sidewall metal (TiN, TaN (high-resistance), and a-C). The middle row in FIG. 7 omits the projection liner. The rightmost view in the bottom row includes a projection liner 251, 253 over the whole surface.

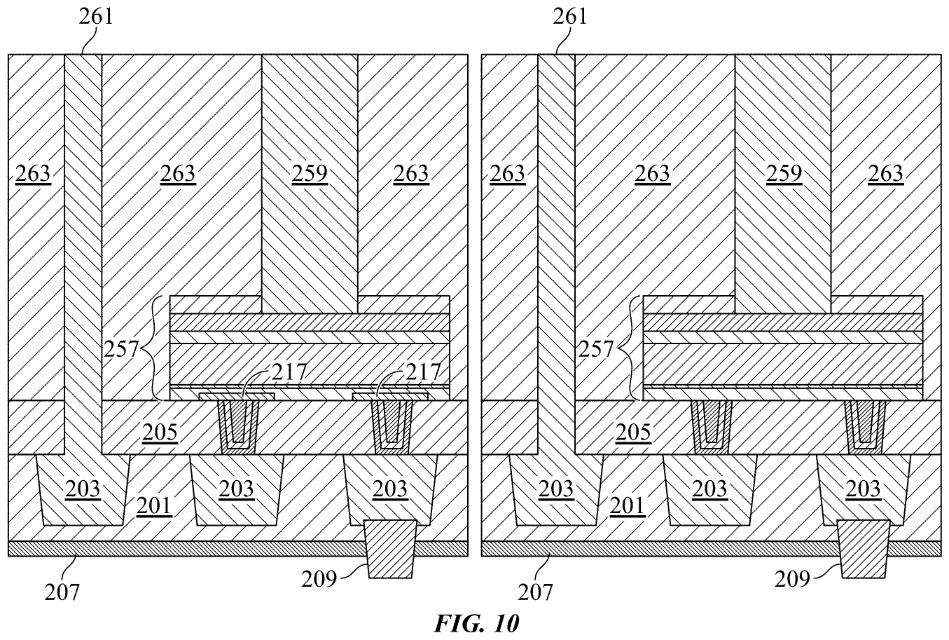

FIG. 10 shows formation of top electrical contact 259 which connects to the TiN top electrode 233. Note also bottom contact 261 which connects to landing pad 203. Suitable materials for the contacts include Tungsten (W) and Copper (Cu). Material 263 can be low-k dielectric or TEOS like 201. Stack 257 includes layers 225, 227, 229, 231, 233, 235 or option 248.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary phase change memory semiconductor structure includes a substrate (e.g., low k dielectric, TEOS 201 and NBLoK, SiN, SiCN 207). Also included is a landing pad 203 located in the substrate. As used herein, the “landing pad” refers to the bottom metal under the heater which connects to the bottom Cu wiring. A dielectric 205 is located outwardly of the substrate, and a heater element 211, 213, 215 is located in the substrate outward of the landing pad. A stack includes an inner undoped chalcogenide layer 225 outward of the dielectric, a doped chalcogenide layer 229 or 237, 241, 245 outward of the inner undoped chalcogenide layer, and an outer undoped chalcogenide layer 231 or 247 outward of the doped chalcogenide layer. In a non-limiting example, the chalcogenide includes GST. Also included is at least one lateral conductive metal layer 227 or 249 associated with the stack.

In one or more embodiments, the at least one lateral conductive metal layer 249 is located outward of the outer undoped chalcogenide layer 231, and a projection liner 217 is located in the inner undoped chalcogenide layer 225 outward of the heater element. Some such embodiments further include a second lateral conductive metal layer 227 located between the inner undoped chalcogenide layer and the doped chalcogenide layer. Some such embodiments further include a sidewall layer 251 (e.g., side ATE lines such as TiN, TaN (high-resistance), and a-C or Si, Ge, or any semiconductor also on the sidewall, to provide current path and thermal confinement) on a sidewall of the structure.

In one or more embodiments, the at least one lateral conductive metal layer 227 is located between the inner undoped chalcogenide layer 225 and the doped chalcogenide layer 229. Some such embodiments further include a second lateral conductive metal layer 249 located outward of the outer undoped chalcogenide layer 231. Some such embodiments further include a sidewall layer 251 (e.g., side ATE lines such as TiN, TaN (high-resistance), and a-C or Si, Ge, or any semiconductor also on the sidewall, to provide current path and thermal confinement) on a sidewall of the structure.

In one or more embodiments, the at least one lateral conductive metal layer 227 is located between the inner undoped chalcogenide layer 225 and the doped chalcogenide layer 229, and an all-around projection liner 253 is located between the inner undoped chalcogenide layer and the heater element. Some such embodiments further include a second lateral conductive metal layer 249 located outward of the outer undoped chalcogenide layer 231. Some such embodiments further include a sidewall layer 251 (e.g., side ATE lines such as TiN, TaN (high-resistance), and a-C or Si, Ge, or any semiconductor also on the sidewall, to provide current path and thermal confinement) on a sidewall of the structure.

In general, references to the outer undoped chalcogenide layer 231 are equally applicable to layer 247. Furthermore, references to the at least one lateral conductive metal layer 227 being located between the inner undoped chalcogenide layer 225 and the doped chalcogenide layer 229 are equally applicable to at least one lateral conductive metal layer 227 being located between inner undoped chalcogenide layer 225 and doped chalcogenide layer 237.

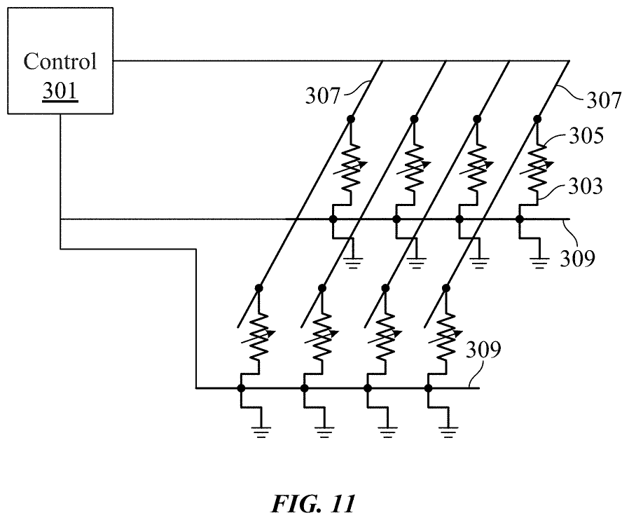

In another aspect, referring to FIG. 11, a phase change memory semiconductor array includes a plurality of word lines 309; a plurality of bit lines 307 (only two are numbered to avoid clutter) intersecting the plurality of word lines at a plurality of cell locations; and a plurality of access devices 303 (e.g., nFETs, pFETs, BJTs), controlled by the word lines, at the plurality of cell locations. Also included are a plurality of phase change memory cells 305 located at the plurality of cell locations. The cells 305 can be any of the kinds of cells disclosed herein. Thus, each of the phase change memory cells includes a substrate portion (e.g., 201, 207—each cell can be on the same substrate); a landing pad 203 located in the substrate portion; a dielectric portion 205 (can be same layer for every cell) located outwardly of the substrate portion; a heater element 211, 213, 215 located in the substrate portion outward of the landing pad; a stack including an inner undoped chalcogenide layer 225 outward of the dielectric, a doped chalcogenide layer 229 or 237, 241, 245 outward of the inner undoped chalcogenide layer, and an outer undoped chalcogenide layer 231 or 247 outward of the doped chalcogenide layer. Also included are at least one lateral conductive metal layer 227 or 249 associated with the stack; and a top electrode 233 outward of the outer undoped chalcogenide layer. The top electrode or the landing pad is coupled to a corresponding one of the bit lines and the other of the top electrode or the landing pad is coupled to a corresponding one of the access devices; for example, wiring connection 209 is connected via bottom wiring 261 to access device 303 and top contact 259 is connected to top wiring for packaging. Note that in FIG. 10, middle and right-hand elements 203 can have wiring 261 out of the plane of the figure.

In one or more embodiments, the phase change memory semiconductor array further includes control circuitry 301 coupled to the word lines and the bit lines and configured to cause weights of a neural network to be stored in plurality of phase change memory cells. In one or more embodiments, the weights are thus stored in the cells.

In another aspect, a method of forming a phase change memory semiconductor structure includes (FIG. 3) depositing a dielectric outwardly of a substrate having a landing pad located therein; patterning the dielectric with a heater formation cavity; and forming a heater element in the heater formation cavity. The method further includes (FIGS. 4-6) forming a stack outward of the dielectric, the stack including an inner undoped chalcogenide layer outward of the dielectric, a doped chalcogenide layer outward of the inner undoped chalcogenide layer, and an outer undoped chalcogenide layer outward of the doped chalcogenide layer; and forming at least one lateral conductive metal layer associated with the stack.

One or more embodiments further include forming a projection liner 217, 253 outward of the heater element and inward of the stack.

In one or more embodiments, forming the at least one lateral conductive metal layer includes forming the at least one lateral conductive metal layer between the inner undoped chalcogenide layer and the doped chalcogenide layer (see layer 227). Some such embodiments further include forming a second lateral conductive metal layer 249 outward of the outer undoped chalcogenide layer. Some such embodiments further include forming a sidewall layer 251 on a sidewall of the structure (e.g., side ATE lines such as TiN, TaN (high-resistance), and a-C or Si, Ge, or any semiconductor also on the sidewall, to provide current path and thermal confinement).

In one or more embodiments, forming the at least one lateral conductive metal layer includes forming the at least one lateral conductive metal layer between the inner undoped chalcogenide layer and the doped chalcogenide layer (see layer 227).

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having PCM cells therein.

An integrated circuit in accordance with aspects of the present inventions can be employed in essentially any application and/or electronic system where PCM cells would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A phase change memory semiconductor structure comprising:
a substrate;
a landing pad located in the substrate;
a dielectric located outwardly of the substrate;
a heater element located in the substrate outward of the landing pad;
a stack including an inner undoped chalcogenide layer outward of the dielectric, a doped chalcogenide layer outward of the inner undoped chalcogenide layer, and an outer undoped chalcogenide layer outward of the doped chalcogenide layer; and
at least one lateral conductive metal layer associated with the stack.

2. The structure of claim 1, wherein said at least one lateral conductive metal layer is located outward of said outer undoped chalcogenide layer, further comprising a projection liner located between said inner undoped chalcogenide layer and said heater element.

3. The structure of claim 2, further comprising a second lateral conductive metal layer located between said inner undoped chalcogenide layer and said doped chalcogenide layer.

4. The structure of claim 3, further comprising a sidewall layer on a sidewall of said structure.

5. The structure of claim 1, wherein said at least one lateral conductive metal layer is located between said inner undoped chalcogenide layer and said doped chalcogenide layer.

6. The structure of claim 5, further comprising a second lateral conductive metal layer located outward of said outer undoped chalcogenide layer.

7. The structure of claim 6, further comprising a sidewall layer on a sidewall of said structure.

8. The structure of claim 1, wherein said at least one lateral conductive metal layer is located between said inner undoped chalcogenide layer and said doped chalcogenide layer, further comprising an all-around projection liner located between said inner undoped chalcogenide layer and said heater element.

9. The structure of claim 8, further comprising a second lateral conductive metal layer located outward of said outer undoped chalcogenide layer

10. The structure of claim 6, further comprising a sidewall layer on a sidewall of said structure.

11. A method of forming a phase change memory semiconductor structure, comprising:
depositing a dielectric outwardly of a substrate having a landing pad located therein;
patterning the dielectric with a heater formation cavity;
forming a heater element in the heater formation cavity;
forming a stack outward of the dielectric, the stack including an inner undoped chalcogenide layer outward of the dielectric, a doped chalcogenide layer outward of the inner undoped chalcogenide layer, and an outer undoped chalcogenide layer outward of the doped chalcogenide layer; and
forming at least one lateral conductive metal layer associated with the stack.

12. The method of claim 11, further comprising forming a projection liner outward of said heater element and inward of said stack.

13. The method of claim 11, wherein forming said at least one lateral conductive metal layer comprises forming said at least one lateral conductive metal layer between said inner undoped chalcogenide layer and said doped chalcogenide layer.

14. The method of claim 13, further comprising forming a second lateral conductive metal layer outward of said outer undoped chalcogenide layer.

15. The method of claim 14, further comprising forming a sidewall layer on a sidewall of said structure.

16. The method of claim 11, wherein forming said at least one lateral conductive metal layer comprises forming said at least one lateral conductive metal layer between said inner undoped chalcogenide layer and said doped chalcogenide layer.

17. A phase change memory semiconductor array comprising:
a plurality of word lines;
a plurality of bit lines intersecting said plurality of word lines at a plurality of cell locations;
a plurality of access devices, controlled by said word lines, at said plurality of cell locations; and
a plurality of phase change memory cells located at said plurality of cell locations, each od said phase change memory cells comprising:
a substrate portion;
a landing pad located in the substrate portion;
a dielectric portion located outwardly of the substrate portion;
a heater element located in the substrate portion outward of the landing pad;
a stack including an inner undoped chalcogenide layer outward of the dielectric, a doped chalcogenide layer outward of the inner undoped chalcogenide layer, and an outer undoped chalcogenide layer outward of the doped chalcogenide layer;
at least one lateral conductive metal layer associated with the stack; and
a top electrode outward of the outer undoped chalcogenide layer;
wherein one of said top electrode and said landing pad is coupled to a corresponding one of said bit lines and another of said top electrode and said landing pad is coupled to a corresponding one of said access devices.

18. The phase change memory semiconductor array of claim 17, further comprising control circuitry coupled to said word lines and said bit lines and configured to cause weights of a neural network to be stored in plurality of phase change memory cells.

19. The phase change memory semiconductor array of claim 18, wherein each cell further comprises a projection liner located between said inner undoped chalcogenide layer and said heater element.

20. The phase change memory semiconductor array of claim 18, wherein each cell further comprises a sidewall layer on a sidewall of said cell.
